(19) United States
(12) Patent Application Publication
(10) Pub. No.: US 2002/0168848 A1
(43) Pub. Date: Nov. 14, 2002

(54) Method of fabricating an interconnect structure

(76) Inventors: Yun-Liang Ouyang, Hsinchu (TW); Chao-Yuan Huang, Hsinchu (TW)

Correspondence Address: BIRCH STEWART KOLASCH & BIRCH, PO BOX 747, FALLS CHURCH, VA, 22040-0747, US

(21) Appl. No.: 09/933,199

(22) Filed: Aug. 21, 2001

(30) Foreign Application Priority Data
May 10, 2001 (TW) 90111158

(51) Int. Cl. H01L 21/4763

(52) U.S. Cl. 438/637

(57) ABSTRACT

The present invention provides a method of fabricating an interconnect structure. First, a semiconductor substrate comprising a conductive region containing a metal line and a hole is provided. Next, a titanium layer is formed on the semiconductor substrate. Next, a first titanium nitride layer is formed on the titanium layer by chemical vapor deposition. Finally, a second titanium nitride layer is formed on the first titanium nitride layer by physical vapor deposition.

### BACKGROUND OF THE INVENTION

1. Field of the Invention

The present invention relates in general to the fabrication of an interconnect structure. In particular, the present invention relates to the formation of a first titanium nitride (TiN) layer by chemical vapor deposition (CVD), then a second titanium nitride (TiN) layer on the first titanium nitride (TiN) layer by physical vapor deposition (PVD) to prevent the first titanium nitride (TiN) layer from oxidizing.

2. Description of the Related Art

FIGS. 1A-1D are section views illustrating a conventional method of manufacturing an interconnect structure.

Referring to FIG. 1A, semiconductor substrate 100 comprises a conductive region 120, which is source/drain doped N/P type ions or interconnect. Next, a dielectric layer 140 is formed on the substrate 100. The dielectric layer 140 is silicon oxide or another low k dielectric. Then, a contact hole 150 is formed by conventional lithography and etching the dielectric layer 140 to expose the conductive region 120. Then, a titanium (Ti) layer 160 is formed by physical vapor deposition.

Referring to FIG. 1B, after the titanium (Ti) layer 160 is formed, a titanium nitride (TiN) layer 180 is formed on the titanium (Ti) layer 160 by CVD. Next, referring to FIG. 1C, a tungsten (w) layer 200 is formed by adding tungsten hexafluoride (WF₆) gas on the titanium nitride (TiN) layer 180 and filling the hole 150. Finally, referring to FIG. 1D, chemical mechanical polishing is performed under suitable conditions to remove the tungsten (w) layer 200 above the dielectric layer 140 and lift the tungsten region 200a in the hole 150. Therefore, the tungsten region 200a, titanium nitride (TiN) layer 180a, and the titanium (Ti) layer 160a constitute a tungsten plug (PG).

In the conventional process, if the titanium nitride layer 180 does not fully cover the titanium layer 160, the added tungsten hexaf luoride gas will react with titanium layer 160 and generate fluorides. The fluorides will cause titanium layer 160 to bulk up and raise resistance. Generally, the step coverage of titanium nitride layer formed by PVD is poor under 0.18 μm process. In other words, the thickness of the titanium nitride layer generated on the sidewalls and bottom of the hole 150 is not enough to prevent the titanium layer from reacting. However, the step coverage of titanium nitride layer formed by CVD is better than by PVD. Therefore, under 0.18 μm process, the titanium nitride layer is formed by CVD to provide better protection to the titanium layer.

Although the titanium nitride layer formed by CVD has good step coverage, the titanium nitride layer tends to oxidize with water when exposed to air and generates titanium oxynitride. In addition, the resistance of the titanium nitride layer increases with time until reaching a saturation value.

Therefore, when the semiconductor device operates, the electric current passing through the titanium nitride layer will generate a large amount of heat, which will damage the semiconductor device.

### SUMMARY OF THE INVENTION

The object of the present invention is to provide a method of fabricating an interconnect structure. According to the object of the present invention, after a first titanium nitride layer is formed on the titanium layer by CVD, a second titanium nitride layer is formed on the first titanium nitride layer by PVD. Since the second titanium nitride layer is more stable than the first, the second titanium nitride layer prevents the first titanium nitride layer from oxidizing.

To achieve the above-mentioned object, the present invention provides a method of fabricating an interconnect structure. First, a semiconductor substrate comprises a conductive region containing a metal line and a hole. Next, a titanium layer is formed on the semiconductor substrate. Next, a first titanium nitride layer is formed on the titanium layer by chemical vapor deposition. Finally, a second titanium nitride layer is formed on the first titanium nitride layer by physical vapor deposition.

In addition, the present invention provides a method of fabricating an interconnect structure. First, a semiconductor substrate comprises a conductive region containing a metal line and a hole. Next, a titanium layer is formed on the semiconductor substrate. Next, a first titanium nitride layer is formed on the titanium layer by chemical vapor deposition, and then a second titanium nitride layer is formed on the first titanium nitride layer by physical vapor deposition. Finally, a tungsten (w) layer is formed on the second titanium nitride (TiN) layer, and the tungsten (w) layer fills the hole.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A-1D are section views illustrating a conventional method of manufacturing an interconnect structure.

FIGS. 2A-2D are section views illustrating a method of manufacturing an interconnect structure according to the embodiment of the present invention.

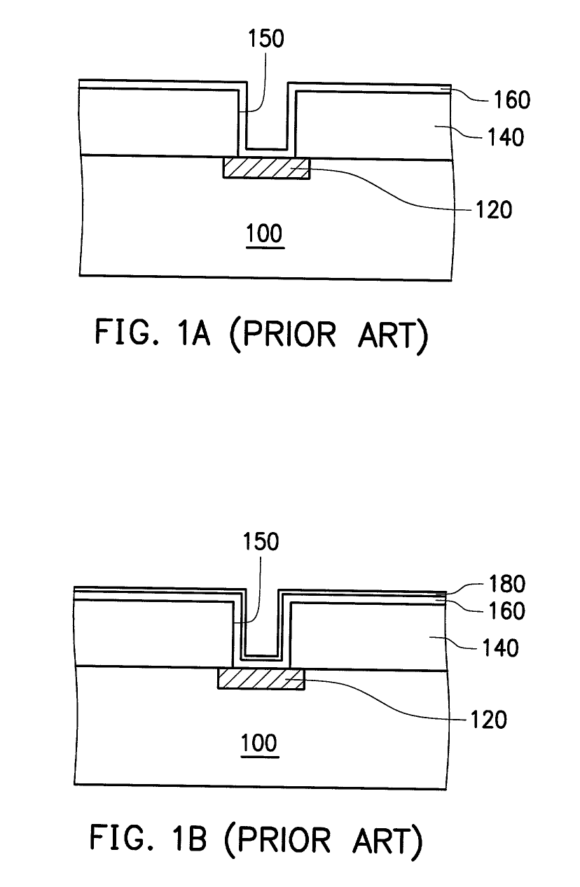

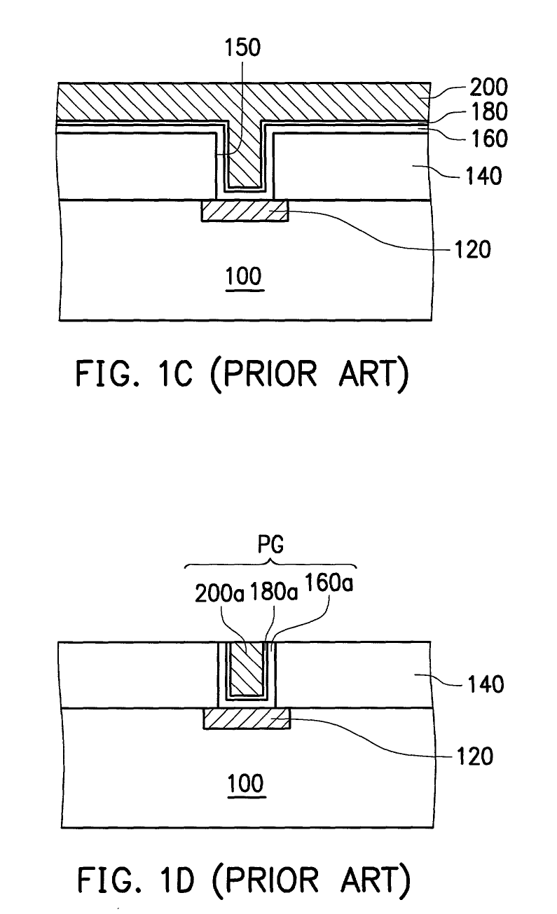

### DETAILED DESCRIPTION OF THE PREFERRED EMBODIMENT

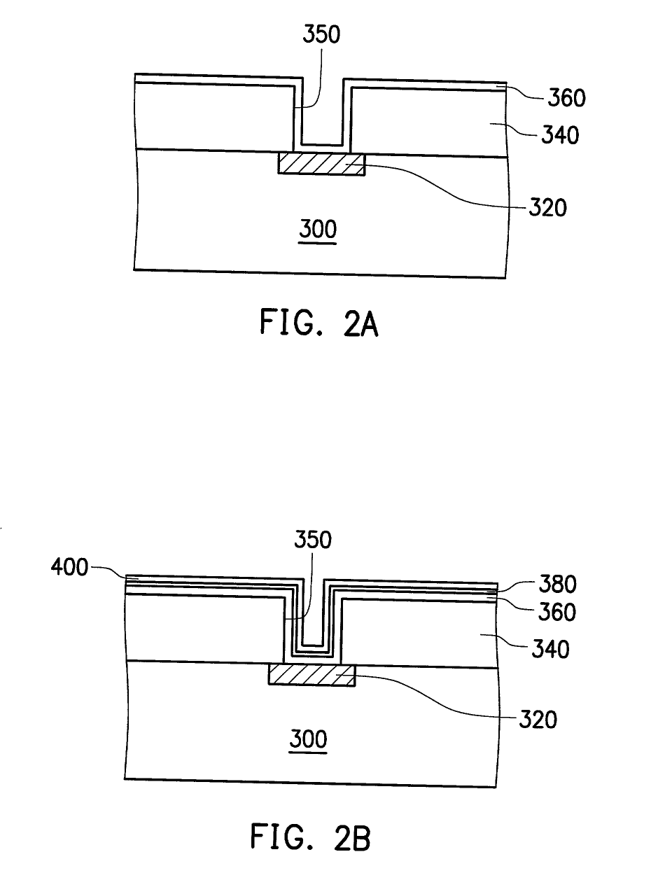

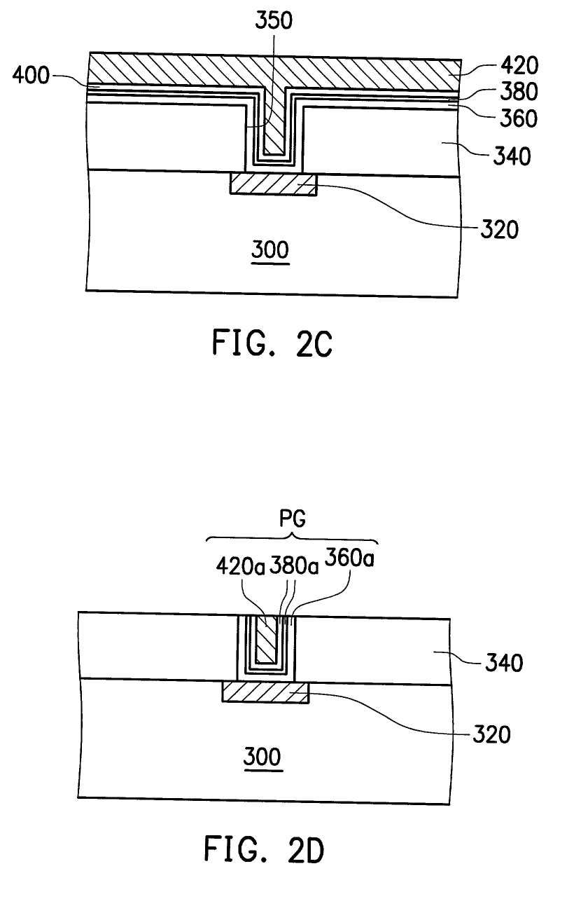

FIGS. 2A-2D are section views illustrating a method of manufacturing an interconnect structure according to the embodiment of the present invention.

Referring to FIG. 2A, semiconductor substrate 300 comprises a conductive region 320, which is source/drain doped N/P type ions or interconnect. Next, a dielectric layer 340 is deposited uniformly on the substrate 300. The dielectric layer 340 is silicon oxide or another low k dielectric. Then, a contact hole 350 is formed by conventional lithography and etching the dielectric layer 340 to expose the conductive region 320. Then, a titanium (Ti) layer 360 is formed by physical vapor deposition.

Referring to FIG. 2B, after the titanium (Ti) layer 360 is formed, a titanium nitride (TiN) layer 380 is formed on the titanium (Ti) layer 360 by CVD. Next, a titanium nitride (TiN) layer 400 is formed on the titanium nitride (TiN) layer 380 by PVD. The titanium nitride (TiN) layer 400 covers the titanium nitride (TiN) layer 380 to prevent the titanium nitride layer 380 from oxidizing with water in the air.

Next, referring to FIG. 2C, a tungsten (w) layer 420 is formed by applying tungsten hexafluoride (WF6) gas to the titanium nitride (TiN) layer 400 and filling the hole 350. Finally, referring to FIG. 2D, chemical mechanical polishing is performed under suitable conditions to remove the tungsten (w) layer 420 above the dielectric layer 340 and lift the tungsten region 420a in the hole 350. Therefore, the tungsten region 420a, titanium nitride (TiN) layer 380a, composed by titanium nitride layer 380 and 340, and the titanium (Ti) layer 360a constitute a tungsten plug (PG).

According to the method of the present invention, a first titanium nitride layer 380 having well step coverage is formed on the titanium layer 360 by CVD to protect titanium layer 360, then a second titanium nitride layer 400 having more stable chemical properties is formed on the first titanium nitride layer 380 by PVD to prevent the first titanium nitride layer from oxidizing 380. Therefore, the aging effect of the titanium nitride layer formed by CVD is avoided. In addition, the queue time of the semiconductor device having titanium nitride layer formed by CVD is increased, so the elasticity of the performed processes are increased.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of fabricating an interconnect structure, comprising the following steps:
providing a semiconductor substrate having a conductive region, wherein the conductive region contains a metal line and a hole;
forming a titanium (Ti) layer on the semiconductor substrate;
forming a first titanium nitride (TiN) layer on the titanium layer (Ti) by chemical vapor deposition; and
forming a second titanium nitride (TiN) layer on the first titanium nitride (TiN) layer by physical vapor deposition.

2. The method as claimed in claim 1, further comprising the step of:
forming a silicon oxide (SiO₂) layer on the semiconductor substrate.

3. The method as claimed in claim 2, wherein the conductive region has a source and a drain.

4. A method of fabricating an interconnect structure, comprising the following steps:
providing a semiconductor substrate having a conductive region, wherein the conductive region contains a metal line and a hole;
forming a titanium (Ti) layer on the semiconductor substrate;
forming a first titanium nitride (TiN) layer on the titanium layer by chemical vapor deposition;
forming a second titanium nitride (TiN) layer on the first titanium nitride (TiN) layer by physical vapor deposition; and
conformally forming a tungsten (w) layer on the second titanium nitride (TiN) layer and filling the hole.

5. The method as claimed in claim 4, further comprising the step of:
forming silicon oxide (SiO₂) layer on the semiconductor substrate.

6. The method as claimed in claim 2, wherein the conductive region has a source and a drain.
